(19) United States
(12) Patent Application Publication
(10) Pub. No.: US 2019/0081147 A1
(43) Pub. Date: Mar. 14, 2019

(54) MOSFET WITH VERTICAL VARIATION OF GATE-PILLAR SEPARATION

(71) Applicants: Polar Semiconductor, LLC, Bloomington, MN (US); Sanken Electric Co., Ltd., Saitama (JP)

(72) Inventors: Peter West, Minneapolis, MN (US); Dosi Dosev, Chanhassen, MN (US); Don Rankila, Farmington, MN (US); Tatsuya Kamimura, St. Louis Park, MN (US); Steve Kosier, Lakeville, MN (US)

(21) Appl. No.: 15/703,699

(22) Filed: Sep. 13, 2017

(51) Int. Cl. H01L 29/423; H01L 29/78; H01L 29/40; H01L 29/10; H01L 29/417; H01L 29/66; H01L 21/28

(52) U.S. Cl. CPC H01L 29/42368; H01L 29/7813; H01L 29/407; H01L 29/1095; H01L 21/28238; H01L 29/66734; H01L 29/66727; H01L 29/401; H01L 29/41741

(57) ABSTRACT

Apparatus and associated methods relate to a trench Metal-Oxide-Semiconductor Field-effect Transistor (MOSFET). The trench MOSFET includes a pair of longitudinal trenches formed in a semiconductor die, thereby forming an intervening longitudinal semiconductor pillar therebetween. Each of the pair of trenches has a field plates dielectrically isolated from a conductive gate. Each of the conductive gates is dielectrically isolated from the intervening semiconductor pillar via a gate dielectric. The thickness of the gate dielectric varies along a vertical dimension of the conductive gate, thereby providing a variation in a separation distance between each conductive gate and the intervening semiconductor pillar. The separation distance decreases from a gate/source overlap region to a channel inversion region. Such a varying separation distance can advantageously improve MOSFET operating parameters.

### BACKGROUND

The thickness of gate dielectrics affects many parameters of a MOSFET. The thickness of the gate dielectric can affect such parameters as: threshold voltage V_{T}; on-resistance R_{ON}; drain-source breakdown voltage BV_{DS}; gate-drain breakdown voltage BV_{GD}, etc. Traditionally, planar MOSFETs have been manufactured to have gate dielectrics that have a uniform thickness. The thickness of a gate dielectric, however, need not be of uniform thickness everywhere. For example, in regions where the conductive gate overlaps the source region, the gate dielectric can be thicker than in regions where the conductive gate needs to create inversion of a channel region. In regions where electrical conduction is primary performed by drift conduction, the gate dielectric might not have the same requirements as in regions where conduction is primarily performed within an inverted channel region. Thus, the present disclosure is directed to apparatus and methods related to MOSFETS with gate dielectric variation between source and drift regions.

### SUMMARY

Apparatus and associated methods relate to a trench Metal-Oxide-Semiconductor Field-effect Transistor (MOSFET). The trench MOSFET includes a semiconductor die including a substrate, an active device region formed upon the substrate, and an interconnection region formed upon the active device region. The active device region and the interconnection region are separated by an interface surface. The trench MOSFET includes a pair of trenches formed in the active device region, each of the trenches extending from the interface surface to a dielectric trench bottom, the trenches laterally separated from one another by an intervening semiconductor pillar. The trench MOSFET includes a conductive gate located within each of the trenches and separated, by a gate dielectric, from the intervening semiconductor pillar by a gate-pillar separation distance. The gate-pillar separation distance continuously decreases from a first depth corresponding to the top of the conductive gate to a second depth below the first depth. The trench MOSFET includes a conductive field plate located within each of the trenches, the conductive field plate electrically connected to a biasing circuit net in the interconnection region. The conductive field plate is located below the conductive gate and vertically separated from the conductive gate by an intervening dielectric. The conductive field plate is laterally separated from the intervening semiconductor pillar by a dielectric material. The trench MOSFET includes a source region in the intervening semiconductor pillar. The source region abuts each of the trenches. The trench MOSFET includes a body region in the intervening semiconductor pillar. The body region abuts each of the trenches between the first and second depths. The trench MOSFET also includes a drift region in the semiconductor pillar contiguously extending from the body region to a drain region therebelow.

Some embodiments relate to a method of manufacturing a trench-gate metal-oxide-semiconductor field-effect transistor (MOSFET). The method begins by etching parallel trenches in a semiconductor die forming an intervening semiconductor pillar therebetween. The trenches vertically extend from a top surface of the semiconductor die. The method continues by oxidizing sidewalls and the bottoms of the trenches leaving a cavity within the oxidized sidewalls and the oxidized bottom of each of the trenches The cavities are then filled with polysilicon. Top portions of the polysilicon are etched, leaving polysilicon gates within the cavity. Then, the tops of the polysilicon gates and the sidewalls above the polysilicon gates are oxidized, thereby tapering the sidewall of the trenches. The oxidization above the polysilicon gates is anisotropically etched, exposing a laterally narrow portion of the top surface where a lateral width of the tapered profile of the intervening semiconductor pillar is smallest. The exposed laterally narrow portion of the top surface of the semiconductor pillar is anisotropically etched, thereby exposing interior sidewalls of the intervening semiconductor pillar where the tapered profile is laterally wider than the exposed laterally narrow portion. A source contact is then formed on the exposed interior sidewalls of the intervening semiconductor pillar.

### BRIEF DESCRIPTION OF THE DRAWINGS

FIG. 1 is a cross-sectional view of an exemplary trench MOSFET with vertical variation of gate-pillar separation.

FIG. 2 is a close-up of a cross-sectioned trench MOSFET with vertical variation of gate-pillar separation.

FIGS. 3A-3M depict a sequence of cross-sectional views of an exemplary trench MOSFET depicted at various steps of manufacture.

FIGS. 4A-4D show trench oxide liners grown using various methods.

### DETAILED DESCRIPTION

Apparatus and associated methods relate to a trench Metal-Oxide-Semiconductor Field-effect Transistor (MOSFET). The trench MOSFET includes a pair of longitudinal trenches formed in a semiconductor die, thereby forming an intervening longitudinal semiconductor pillar therebetween. Each of the pair of trenches has a field plate dielectrically isolated from both a conductive gate and the intervening longitudinal semiconductor pillar. Each of the conductive gates is dielectrically isolated from the longitudinal intervening semiconductor pillar via a gate dielectric. The thickness of the gate dielectric varies along a vertical dimension of the conductive gate, thereby providing a variation in a separation distance between each conductive gate and the intervening semiconductor pillar. The separation distance decreases from a gate/source overlap region to a channel inversion region. Such a varying separation distance can advantageously improve various MOSFET operating parameters.

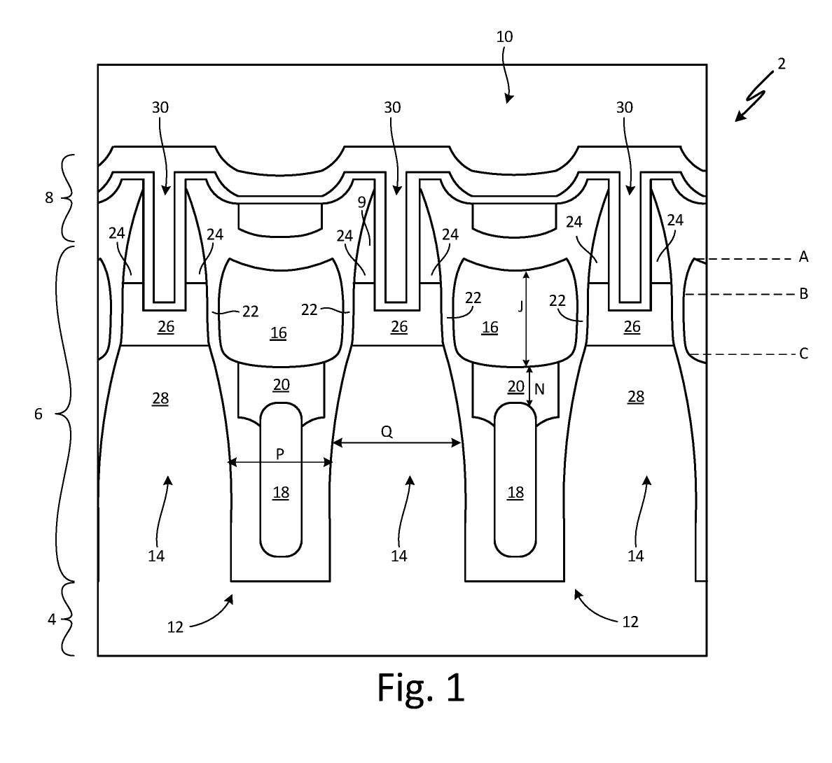

FIG. 1 is a cross-sectional view of an exemplary trench MOSFET with vertical variation of gate-pillar separation. In FIG. 1, exemplary trench MOSFET 10 is formed in semiconductor die 2. Semiconductor die 2 includes substrate 4, active device region 6 formed upon substrate 4, and interconnection region 8 formed upon active device region 6. Active device region 6 and interconnection region 8 are separated by interface surface 9.

Trench MOSFET 10 includes a sequence of longitudinal trenches 12 formed in active device region 6 extending from interface surface 9 to a dielectrically lined trench bottom. Longitudinal trenches 12 define intervening longitudinal semiconductor pillars 14 between adjacent pairs of longitudinal trenches 12. Each of longitudinal trenches 12 has conductive gate 16 and conductive field plate 18 vertically separated from one another by field-plate/gate dielectric 20. Conductive gate 16 is vertically separated from field plate 18 by a separation distance (N). Conductive gate 16 is laterally separated from intervening semiconductor pillar 14 by gate dielectric 22. The thickness of gate dielectric 22 defines a gate-pillar separation distance. The gate-pillar separation distance varies along the vertical dimension J, which defines the vertical extent of conductive gate 16. The gate-pillar separation distance is greatest at a first depth location A corresponding to the top of conductive gate 16 and then continuously decreases to a second depth location B below a first depth location A.

In some embodiments, the gate-pillar separation distance is substantially constant from the second depth location B to a third depth location C corresponding to the bottom of conductive gate 16. Intervening longitudinal semiconductor pillars 14 each have formed therein source region 24, body region 26 and a drift region 28. In some embodiments, trench MOSFET 10 includes a second drift region between drift region 28 and body region 26. The impurity concentration of the second drift region is larger than that of drift region 28 and smaller than that of an underlying drain region. An interface between the second drift region and drift region 28 is deeper than a top of the field plate 18.

Body region 26 of intervening longitudinal semiconductor pillar 14 abuts each of the trenches between the first depth location A and the third depth location C. The vertically-varying gate-pillar separation is configured to permit conductive gate 16 to substantially invert the carrier population within abutting body region 26 from source region 24 to the drift region 28, with appropriate biasing conditions. Such inversion of the carrier population results from biasing conditions between conductive gate 16 and body region 26 across gate dielectric 22.

Each of the sequence of longitudinal trenches 12 has a lateral width P that varies as a function of depth location. In the depicted embodiment, the lateral width of longitudinal trenches 12 is larger at the first depth location A than at the third depth location C. Conversely, each of the intervening longitudinal semiconductor pillars 14 has a lateral width Q that varies as a function of depth location in a manner that is complementary to the manner in which the lateral width of longitudinal trenches 12 varies as a function of depth location. Thus, the lateral width of each of intervening longitudinal semiconductor pillars 14 is smaller at the first depth location A than at the third depth location C.

Source regions 24 and body regions 26 of intervening longitudinal semiconductor pillars 14 are simultaneously contacted with contacts 30. Contacts 30 are formed at sidewalls and bottoms of contact trenches formed in intervening longitudinal semiconductor pillars 14. Electrical contact is formed with source regions 24 at the sidewalls of the contact trenches, and electrical contact is formed with body regions 26 at the bottoms of the contact trenches or at the bottoms and the sidewalls of the contact trenches.

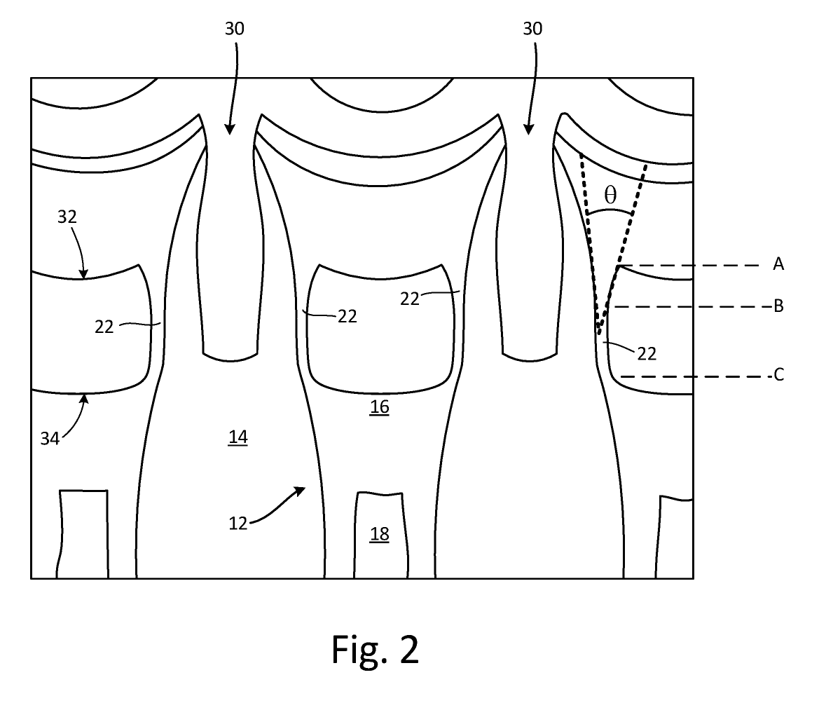

FIG. 2 is a close-up of a cross-sectioned trench MOSFET with vertical variation of gate-pillar separation. In FIG. 2, the dimensions an exemplary gate dielectric can be seen. Note the particular shape of trenches 12 and conductive gates 16 in the depicted embodiment. Conductive gate 16 has a crescent shape with concave portion 32 facing and/or aligned toward the top of the trench 12 and convex portion 34 facing and/or aligned toward the bottom of trench 12. The lateral width of conductive gate 16 increases from first depth location A corresponding to the top of conductive gate 16 to second depth location B. The gate-pillar separation distance continuously decreases from first depth location A to second depth location B in a complementary fashion. The gate-pillar separation distance then remains substantially constant from second depth location B to third depth location C, which substantially corresponds to a bottom of conductive gate 16. Also note that the lateral width of the trench 12 continuously decreases from second depth location B to third depth location C.

Because gate dielectric 22 has a lateral width at depth location A that is greater than the lateral width at depth location B, various metrics can be defined to characterize the variation in lateral width of gate dielectric 22 as a function of depth location. In the depicted figure, angle θ characterizes the decreasing lateral width of gate dielectric 22 as the depth location increases. In some embodiments, the angle θ can be greater than 15, 18, 22, or 30 degrees. In some embodiments, the ratio of the lateral width of gate dielectric 22 at first depth location A to lateral width of gate dielectric 22 at second depth location B is greater than 1.5, 1.75 or 2.0.

The depicted profiles of conductive-gate 16 and trench 12 can facilitate the implantation, after the conductive gate has been fabricated, of various dopant species into intervening semiconductor pillar 14. Off-angle implantations can be masked by conductive gate 16, permitting implantation through gate dielectric 22 at, near, and even slightly below the top of conductive gate 16. Because gate dielectric 22 has a larger lateral width near the top of conductive gate 16, such off-angle implantations can achieve dopant profiles that extend to depth locations somewhat below the top of conductive gate 16. The lateral width of intervening semiconductor pillars 14 is narrower than the lateral width of the trenches 12 at first and second depth locations A and B. The lateral width of the intervening semiconductor pillars increases as the depth location increases. In some embodiments, the lateral width of each of intervening semiconductor pillars 14 is greater than the lateral width of each of trenches 12 at or below the third depth location C.

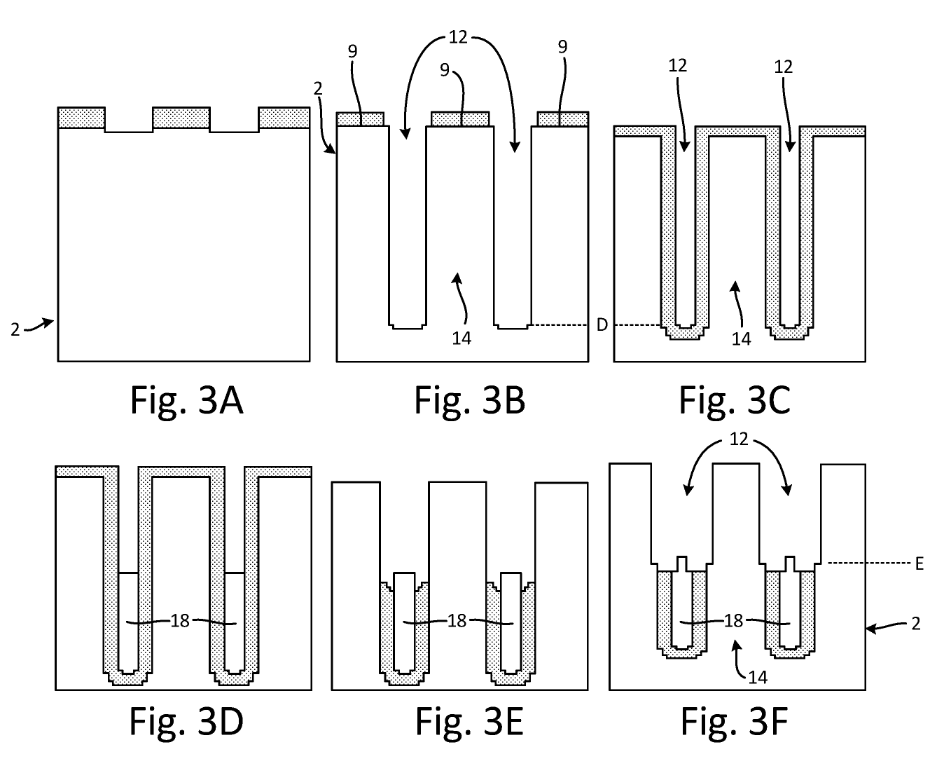

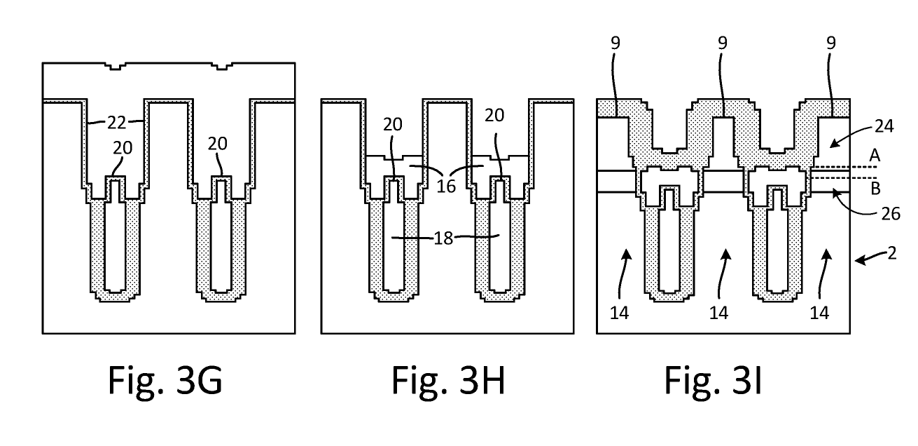

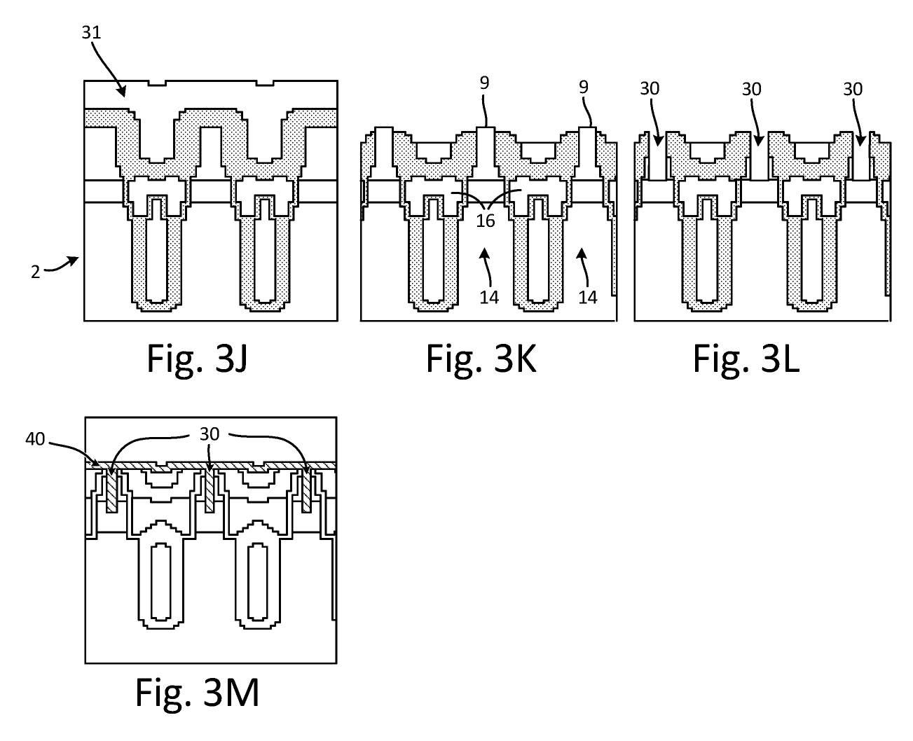

FIGS. 3A-3M depict a sequence of cross-sectional views of an exemplary trench MOSFET depicted at various steps of manufacture. In FIG. 3A, a patterned mask is formed on a top surface of a semiconductor die 2. In FIG. 3B, parallel longitudinal trenches 12 in semiconductor die 2 are etched using the patterned mask. The parallel longitudinal trenches 12 form and/or define intervening longitudinal semiconductor pillar 14 therebetween. The longitudinal trenches 12 vertically extend from top surface 9 of the semiconductor die to fourth depth location D corresponding to the bottoms of the longitudinal trenches. In FIG. 3C, dielectric linings are formed on the sidewalls and bottoms of the longitudinal trenches 12. These dielectric linings are formed by oxidizing the sidewalls and the bottoms of the longitudinal trenches 12. The oxidation is performed so as to leave a cavity within the oxidized sidewalls and the oxidized bottom of each of the longitudinal trenches 12.

In FIG. 3D, the cavities are filled with polysilicon, and then the polysilicon has been etched so as to leave polysilicon field plates 18 in a bottom portion of each of the cavities. In FIG. 3E, dielectric linings are etched from regions above polysilicon field plates 18 to regions under the top of polysilicon field plates 18, thereby exposing the sidewalls of the longitudinal trenches 12 above the polysilicon field plates 18. FIG. 3F depicts semiconductor die 2 after the exposed sidewalls and tops of polysilicon field plates 18 and a part of the sidewall of longitudinal trenches 12 under polysilicon field plates 18 are sacrificially oxidized and then the sacrificial oxide is removed from the sidewalls above the top portions of polysilicon field plates 18, thereby creating tapered profiles to trenches 12 and intervening semiconductor pillars 14. Such a manufactured tapered profile, at a fifth depth location E under the tops of polysilicon field plates 18, results in vertical profiles of the longitudinal trenches 12 and the intervening semiconductor pillar 14 as depicted. Also, these steps again expose the cavity sidewalls above polysilicon field plates 18.

In FIG. 3G, the exposed sidewalls and the top portions of polysilicon field plates 18 are again oxidized to form gate dielectric 22 and field plate/gate dielectric 20 thereon. FIG. 3G also depicts top portions of the cavities filled with polysilicon. The polysilicon in the top portions of each cavity is separated from the polysilicon field plate by field-plate/gate dielectric 20. In FIG. 3H, the top portions of the polysilicon are etched to the top surface 9 of semiconductor die 2, leaving polysilicon gates 16 within the cavity and above polysilicon field plates 18. In FIG. 3I, source region 24 and body region 26 are formed in longitudinal semiconductor pillar 14 and the tops of polysilicon gates 16 and the sidewalls above polysilicon gates 16 and the top of surface 9 of semiconductor die 2 are oxidized. This oxidation forms a tapered profile, between first depth location A corresponding to the tops of polysilicon gates 16 and a depth of the source region (e.g., second depth location B), the vertical profiles of the longitudinal trenches 12, intervening semiconductor pillar 14, and gate dielectric 22. This oxidation also forms a tapered profile of the intervening semiconductor pillars 14 above the depth location A. Such a tapered profile of intervening semiconductor pillars 14 facilitates creating self-aligned source and body contacts via an anisotropic etch of an exposed top surface 9 of intervening semiconductor pillars 14, as will be described below.

In FIG. 3J, BPSG glass 31 has been deposited and reflowed, thereby planarizing a top surface of BPSG glass 31. In FIG. 3K, the BPSG glass above polysilicon gates 16 and a laterally narrow portion of top surface 9 where a lateral width of the tapered profile of intervening semiconductor pillar 14 is smallest has been etched to a level below top surface 9 of intervening semiconductor pillars 14.

In FIG. 3L, the exposed laterally narrow portion of the top surface 9 of the semiconductor pillar has been anisotropically etched, thereby exposing interior sidewalls and bottom of contact trench 30 within intervening semiconductor pillars 14. Because the tapered profile of each of intervening semiconductor pillars 14 is laterally wider at the bottom of contact trench 30 than at the top of contact trench 30, such an anisotropic etch exposes sidewalls of intervening semiconductor pillars 14 as the etch progresses. In other words, the etching process creates a substantially vertical profile of contact trench 30 within an expanding profile of intervening semiconductor pillar 14. Source region 24 has been formed within the expanding profile of intervening semiconductor pillar 14. In order to keep contact trench 30 from coming too close to dielectric 22 near gate 16, the top portion of trench 12 has been tapered. Dielectric 22 is formed on the surface of semiconductor pillar 14 between trench 12 and contact trench 30.

In FIG. 3M, metallization 40 has been deposited so as to make electrical contact with source region 24 and body region 26 of trench MOSFET 10. Such source region 24 and body region 26 have been formed on the exposed interior sidewalls and bottom of contact trenches 30 within intervening semiconductor pillars 14, respectively. In some embodiments, space between each of longitudinal trenches 12 and contact trenches 30 can be reduced using such self-aligned processing techniques. In some embodiments, area of contact trenches 30 can be increased between metallization 40 and source region 24 and/or body region 26, without increasing widths of contact trenches 30 (e.g., a portion of the contact area is on sidewalls of contact trenches 30). Contact resistance and/or contact variation can be reduced in some embodiments, due to such self-aligned processing techniques.

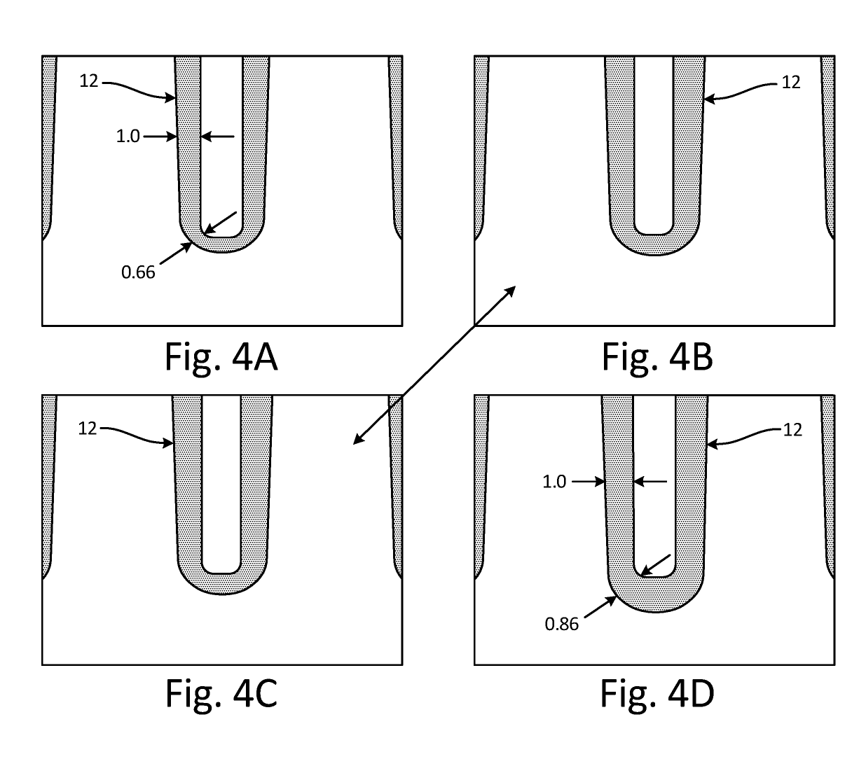

FIGS. 4A-4D show trench oxide liners grown using various methods. These experiments in trench oxidation were performed in an effort to provide high breakdown between the drain-biased semiconductor regions outside of the trench 12 and the field plate inside the trench 12. The bottom corner of the trench 12 can be the Achilles heel or the location most susceptible to breakdown in some embodiments. Breakdowns can occur at these bottom corners if the oxide thickness in these locations is significantly thinner than in other locations of the trench 12.

FIGS. 4A-4D are cross-sections of trenches 12 having been oxidized and then having the remaining cavity filled with polysilicon (e.g., polysilicon field plates 18). Each of the four trenches 12 has been first oxidized with a sacrificial oxide of either 230 Å or 500 Å. The sacrificial oxide is then stripped and a wet oxidation is performed at either 1100° C. or 1150° C. The purpose of the sacrificial oxidation and strip is to round the sharp corners of the trench 12, especially at the bottom corners. FIGS. 4A-4B depict the full-factorial combination of these sacrificial oxide thicknesses and temperatures used during wet oxidation. FIGS. 4A and 4B depict trenches 12 formed using a 230 Å sacrificial oxide. FIGS. 4C and 4D depict trenches 12 formed using a 500 Å sacrificial oxide. FIGS. 4A and 4C depict trenches 12 formed using a temperature of 1100° C. during wet oxidation. FIGS. 4B and 4D depict trenches 12 formed using a temperature of 1150° C. during wet oxidation.

The experimentally obtained best oxide uniformity of the full factorial combination of experiments is depicted in FIG. 4D. This best oxide uniformity was the result of using a sacrificial oxide thickness of 500 Å and a wet oxidation temperature of 1150° C. The thickness of such a sacrificial oxide at the bottom of the trenches 12 can be between two-thirds and one times that of the thickness at the sidewalls of the trenches 12. This best oxide uniformity has a ratio of oxidation thicknesses of the bottom corner to the sidewall locations of 0.86.

### Discussion of Possible Embodiments

The following are non-exclusive descriptions of possible embodiments of the present invention.

Apparatus and associated methods relate to trench Metal-Oxide-Semiconductor Field-effect Transistor (MOSFET). The trench MOSFET includes a semiconductor die including a substrate, an active device region formed upon the substrate, and an interconnection region formed upon the active device region. The active device region and the interconnection region are separated by an interface surface. The trench MOSFET includes a pair of trenches formed in the active device region. Each of the pair of trenches extends from the interface surface to a dielectric trench bottom. The trenches are laterally separated from one another by an intervening semiconductor pillar. The trench MOSFET includes a conductive gate located within each of the trenches and separated, by a gate dielectric, from the intervening semiconductor pillar by a gate-pillar separation distance. The gate-pillar separation distance decreases from a first depth location corresponding to the top of the conductive gate to a second depth location below the first depth location. The trench MOSFET includes a conductive field plate located within each of the trenches. The conductive field plate is located below the conductive gate and is vertically separated from the conductive gate by an intervening dielectric. The conductive field plate is laterally separated from the intervening semiconductor pillar by a dielectric material. The trench MOSFET includes a source region in the intervening semiconductor pillar, the source region abutting each of the trenches. The trench MOSFET includes a body region in the intervening semiconductor pillar. The body region abuts each of the trenches below the first depth location. The trench MOSFET also includes a drift region in the semiconductor pillar contiguously extending from the body region to a drain region therebelow.

The trench MOSFET of the preceding paragraph can optionally include, additionally and/or alternatively, any one or more of the following features, configurations and/or additional components:

A further embodiment of the foregoing trench MOSFET, wherein the gate-pillar separation distance can be substantially constant from the second depth location to a third depth location below the second depth location.

A further embodiment of any of the foregoing trench MOSFETs, wherein a lateral width of each of the pair of trenches can continuously increase from the third depth location to the second depth location.

A further embodiment of any of the foregoing trench MOSFETs, wherein a lateral width of the intervening semiconductor pillar can continuously decrease from the third depth location to the second depth location.

A further embodiment of any of the foregoing trench MOSFETs, wherein a lateral width of the intervening semiconductor pillar can continuously decrease from the third depth location to the first depth location.

A further embodiment of any of the foregoing trench MOSFETs, wherein a lateral width of the intervening semiconductor pillar can continuously decrease from the third depth location to a top of the intervening semiconductor pillar.

A further embodiment of any of the foregoing trench MOSFETs, wherein the intervening semiconductor pillar can have a lateral dimension that is narrowest at a top of the intervening semiconductor pillar.

A further embodiment of any of the foregoing trench MOSFETs, wherein a source/body contact can be formed in an etched contact trench in the intervening semiconductor pillar from a top of the intervening semiconductor pillar to at least the first depth location corresponding to the top of the conductive gate.

A further embodiment of any of the foregoing trench MOSFETs, wherein the source/body contact can include a metal contact made with the source region at a sidewall of the etched contact trench and a metal contact made with the body region at a bottom and a sidewall of the etched contact trench.

A further embodiment of any of the foregoing trench MOSFETs, wherein a heavily doped body contact region can be implanted into a bottom of the etched contact trench.

A further embodiment of any of the foregoing trench MOSFETs, wherein the pair of trenches can have dielectric sidewalls, and the dielectric sidewalls of the pair of trenches can have a thickness at a depth location above the first depth location that is greater than the gate-pillar separation distance at the second depth location.

A further embodiment of any of the foregoing trench MOSFETs, wherein the etched contact can be self-aligned with the dielectric sidewalls of the pair of trenches, thereby centering the etched contact within the intervening semiconductor pillar.

A further embodiment of any of the foregoing trench MOSFETs, wherein a ratio of a lateral width of each of the pair of trenches to a lateral width of the intervening semiconductor pillar can be greater than one, as measured at the first depth location.

Some embodiments relate to a method of manufacturing a trench-gate Metal-Oxide-Semiconductor Field-Effect Transistor (MOSFET). The method includes etching two parallel trenches in a semiconductor die forming an intervening semiconductor pillar therebetween, the two trenches vertically extending from a top surface of the semiconductor die. The method includes oxidizing sidewalls and bottoms of the two trenches leaving a cavity within the oxidized sidewalls and the oxidized bottom of each of the two trenches. The method includes filling the cavities with polysilicon. The method includes etching the top portions of the polysilicon leaving polysilicon gates within the cavity. The method includes forming a source region in the semiconductor pillars. The method includes oxidizing the tops of the polysilicon gates and the sidewalls of the two trenches above the polysilicon gates, thereby tapering the sidewalls of the two trenches. The method also includes anisotropically etching the oxidization above the polysilicon gates exposing a laterally narrow portion of the top surface where a lateral width of the tapered profile of the intervening semiconductor pillar is smallest.

The method of the preceding paragraph can optionally include, additionally and/or alternatively, any one or more of the following features, configurations and/or additional components:

A further embodiment of the foregoing method can further include anisotropically etching the exposed laterally narrow portion of the top surface of the semiconductor pillar, thereby exposing interior sidewalls and bottom of a contact trench within the intervening semiconductor pillar. The method can also include forming a source contact on the exposed interior sidewalls of the contact trench.

A further embodiment of any of the foregoing methods can further include forming a body contact on the exposed bottom of the contact trench.

A further embodiment of any of the foregoing methods can further include implanting, after anisotropically etching the exposed laterally narrow portion of the top surface of the semiconductor pillar, a body contact region into the contact trench.

A further embodiment of any of the foregoing methods can further include implanting, after oxidizing the tops of the polysilicon gates and the sidewalls above the polysilicon gates, a source region into the intervening semiconductor pillar.

A further embodiment of any of the foregoing methods, wherein the step of oxidizing sidewalls and the bottoms of the two longitudinal trenches leaving a cavity within the oxidized sidewalls and the oxidized bottom of each of the two longitudinal trenches can include performing a sacrificial oxidation of the sidewalls and the bottoms of the two longitudinal trenches. The step of oxidizing sidewalls and the bottoms of the two longitudinal trenches leaving a cavity within the oxidized sidewalls and the oxidized bottom of each of the two longitudinal trenches can include stripping the sacrificial oxide from the sidewalls and the bottoms of the two longitudinal trenches. The step of oxidizing sidewalls and the bottoms of the two longitudinal trenches leaving a cavity within the oxidized sidewalls and the oxidized bottom of each of the two longitudinal trenches can also include performing a wet oxidation of the sidewalls and the bottoms of the two longitudinal trenches at a temperature greater than 1100° C.

A further embodiment of any of the foregoing methods can further include depositing, before filling top portions of the cavities with polysilicon, a dielectric above the polysilicon field plates within the trenches.

Some embodiments relate to a method for fabricating a trench gate MOSFET. The method includes etching a semiconductor die, thereby forming first trenches and a semiconductor pillar between adjacent pairs of the first trenches. The method includes forming a first insulation layer on a bottom and sidewalls of each of the first trenches and on a top surface of the semiconductor die. The method includes depositing a polysilicon layer on the top surface of the semiconductor die and in the first trenches. The method includes etching part of the polysilicon layer, thereby forming polysilicon gates in each of the trenches, a top surface of the polysilicon gate being lower than the top surface of the semiconductor die. The method includes forming a second insulation layer on the polysilicon gate, on a top portion of the sidewalls of the first trenches, and on the top surface of the semiconductor die. The method includes anisotropically etching part of the second insulation layer, thereby exposing a top part of each semiconductor pillar. The method includes forming a second trench in each exposed top part of the semiconductor pillars. The method also includes forming an electrode in each second trench.

The method of the preceding paragraph can optionally include, additionally and/or alternatively, any one or more of the following features, configurations and/or additional components:

A further embodiment of the foregoing method, wherein forming a second insulation layer on the polysilicon gate, sidewalls of the first trenches, and the top surface of the semiconductor die creates tapered sidewalls of the first trenches. The method further includes forming a source region of a first conductivity type extending from the surface of each semiconductor pillar. The method also includes forming a body region of a second conductivity type below the source region and in each semiconductor pillar.

A further embodiment of any of the foregoing methods, wherein a bottom of each of the second trenches can be deeper than a bottom of each of the source regions.

A further embodiment of any of the foregoing methods, wherein each of the semiconductor pillars laterally can extend from each side of each of the second trenches, and wherein first trenches can be separated from second trenches by the second insulation layer.

A further embodiment of any of the foregoing methods can further include forming a first drift region of the first conductivity type below the body region and in each semiconductor pillar. A bottom of the first drift region can be shallower than a bottom of the first trenches. The method can further include forming a second drift region of the first conductivity type below the first drift region and in each semiconductor pillar. A net impurity concentration of the second drift region can be less than a net impurity concentration of the first drift region. The method can also include forming a drain region below the second drift region. A net impurity concentration of the drain region can be greater than the net impurity concentration of the second drift region.

A further embodiment of any of the foregoing methods can further include forming an isolated polysilicon field plate below the polysilicon gate in each of the first trenches, wherein an interface between first and second drift regions is deeper than a top surface of the polysilicon field plate.

A further embodiment of any of the foregoing methods can further include forming a third insulation layer that includes of BPSG on the second insulation layer before etching part of the second insulation layer.

A further embodiment of any of the foregoing methods, wherein a thickness of the first insulation layer at the bottom of each of the first trenches can be between two-thirds and one times a thickness of the first insulation layer at the sidewalls of the corresponding first trench.

A further embodiment of any of the foregoing methods, wherein forming the first insulation layer on the bottom and the sidewalls of each of the first trenches and on the top surface of the semiconductor die can include oxidizing the bottom and the sidewalls of each of the first trenches and the top surface of the semiconductor die using an oxidation temperature greater than 1000° C.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed.

1. A trench Metal-Oxide-Semiconductor Field-effect Transistor (MOSFET) comprising:
a semiconductor die including a substrate, an active device region formed upon the substrate, and an interconnection region formed upon the active device region, the active device region and the interconnection region separated by an interface surface;
a pair of trenches formed in the active device region, each of the pair of trenches extending from the interface surface to a dielectric trench bottom, the trenches laterally separated from one another by an intervening semiconductor pillar;
a conductive gate located within each of the trenches and separated, by a gate dielectric, from the intervening semiconductor pillar by a gate-pillar separation distance, wherein the gate-pillar separation distance decreases from a first depth location corresponding to the top of the conductive gate to a second depth location below the first depth location;
a conductive field plate located within each of the trenches, the conductive field plate located below the conductive gate and vertically separated from the conductive gate by an intervening dielectric, the conductive field plate laterally separated from the intervening semiconductor pillar by a dielectric material;
a source region in the intervening semiconductor pillar, the source region abutting each of the trenches;
a body region in the intervening semiconductor pillar, the body region abutting each of the trenches below the first depth location; and
a drift region in the semiconductor pillar contiguously extending from the body region to a drain region therebelow.

2. The trench MOSFET of claim 1, wherein the gate-pillar separation distance is substantially constant from the second depth location to a third depth location below the second depth location.

3. The trench MOSFET of claim 2, wherein a lateral width of each of the pair of trenches continuously increases from the third depth location to the second depth location.

4. The trench MOSFET of claim 2, wherein a lateral width of the intervening semiconductor pillar continuously decreases from the third depth location to the second depth location.

5. The trench MOSFET of claim 2, wherein a lateral width of the intervening semiconductor pillar continuously decreases from the third depth location to the first depth location.

6. The trench MOSFET of claim 2, wherein a lateral width of the intervening semiconductor pillar continuously decreases from the third depth location to a top of the intervening semiconductor pillar.

7. The trench MOSFET of claim 1, wherein the intervening semiconductor pillar has a lateral dimension that is narrowest at a top of the intervening semiconductor pillar.

8. The trench MOSFET of claim 1, wherein a source/body contact is formed in an etched contact trench in the intervening semiconductor pillar from a top of the intervening semiconductor pillar to at least the first depth location corresponding to the top of the conductive gate.

9. The trench MOSFET of claim 8, wherein the source/body contact includes a metal contact made with the source region at a sidewall of the etched contact trench and a metal contact made with the body region at a bottom and a sidewall of the etched contact trench.

10. The trench MOSFET of claim 8, wherein a heavily doped body contact region is implanted into a bottom of the etched contact trench.

11. The trench MOSFET of claim 8, wherein the pair of trenches have dielectric sidewalls, and the dielectric sidewalls of the pair of trenches have a thickness at a depth location above the first depth location that is greater than the gate-pillar separation distance at the second depth location.

12. The trench MOSFET of claim 11, wherein the etched contact is self-aligned with the dielectric sidewalls of the pair of trenches, thereby centering the etched contact within the intervening semiconductor pillar.

13. The trench MOSFET of claim 1, wherein a ratio of a lateral width of each of the pair of trenches to a lateral width of the intervening semiconductor pillar is greater than one, as measured at the first depth location.

14. A method of manufacturing a trench-gate Metal-Oxide-Semiconductor Field-Effect Transistor (MOSFET), the method comprising:
etching two parallel trenches in a semiconductor die forming an intervening semiconductor pillar therebetween, the two trenches vertically extending from a top surface of the semiconductor die;
oxidizing sidewalls and bottoms of the two trenches leaving a cavity within the oxidized sidewalls and the oxidized bottom of each of the two trenches;
filling the cavities with polysilicon;
etching the top portions of the polysilicon leaving polysilicon gates within the cavity;
forming a source region in the semiconductor pillars;
oxidizing the tops of the polysilicon gates and the sidewalls of the two trenches above the polysilicon gates, thereby tapering the sidewalls of the two trenches; and
anisotropically etching the oxidization above the polysilicon gates exposing a laterally narrow portion of the top surface where a lateral width of the tapered profile of the intervening semiconductor pillar is smallest.

15. The method of claim 14, further comprising:
anisotropically etching the exposed laterally narrow portion of the top surface of the semiconductor pillar, thereby exposing interior sidewalls and bottom of a contact trench within the intervening semiconductor pillar; and
forming a source contact on the exposed interior sidewalls of the contact trench.

16. The method of claim 15, further comprising:
forming a body contact on the exposed bottom of the contact trench.

17. The method claim 15, further comprising:
implanting, after anisotropically etching the exposed laterally narrow portion of the top surface of the semiconductor pillar, a body contact region into the contact trench.

18. The method claim 14, further comprising:
implanting, after oxidizing the tops of the polysilicon gates and the sidewalls above the polysilicon gates, a source region into the intervening semiconductor pillar.

19. The method of claim 14, wherein oxidizing sidewalls and the bottoms of the two longitudinal trenches leaving a cavity within the oxidized sidewalls and the oxidized bottom of each of the two longitudinal trenches comprises:
performing a sacrificial oxidation of the sidewalls and the bottoms of the two longitudinal trenches;
stripping the sacrificial oxide from the sidewalls and the bottoms of the two longitudinal trenches; and
performing a wet oxidation of the sidewalls and the bottoms of the two longitudinal trenches at a temperature greater than 1100° C.

20. The method of claim 14, further comprising:
depositing, before filling top portions of the cavities with polysilicon, a dielectric above the polysilicon field plates within the trenches.

21. A method for fabricating a trench gate MOSFET, the method comprising:
etching a semiconductor die, thereby forming first trenches and a semiconductor pillar between adjacent pairs of the first trenches;
forming a first insulation layer on a bottom and sidewalls of each of the first trenches and on a top surface of the semiconductor die;
depositing a polysilicon layer on the top surface of the semiconductor die and in the first trenches;
etching part of the polysilicon layer, thereby forming polysilicon gates in each of the trenches, a top surface of the polysilicon gate being lower than the top surface of the semiconductor die;
forming a second insulation layer on the polysilicon gate, on a top portion of the sidewalls of the first trenches, and on the top surface of the semiconductor die;
anisotropically etching part of the second insulation layer, thereby exposing a top part of each semiconductor pillar;
forming a second trench in each exposed top part of the semiconductor pillars; and
forming an electrode in each second trench.

22. The method of claim 21, wherein forming a second insulation layer on the polysilicon gate, sidewalls of the first trenches, and the top surface of the semiconductor die creates tapered sidewalls of the first trenches, the method further comprising:
forming a source region of a first conductivity type extending from the surface of each semiconductor pillar; and
forming a body region of a second conductivity type below the source region and in each semiconductor pillar.

23. The method of claim 22, wherein a bottom of each of the second trenches is deeper than a bottom of each of the source regions.

24. The method of claim 22, wherein each of the semiconductor pillars laterally extends from each side of each of the second trenches, and wherein first trenches are separated from second trenches by the second insulation layer.

25. The method of claim 22, further comprising:
forming a first drift region of the first conductivity type below the body region and in each semiconductor pillar, a bottom of the first drift region is shallower than a bottom of the first trenches;
forming a second drift region of the first conductivity type below the first drift region and in each semiconductor pillar, a net impurity concentration of the second drift region less than a net impurity concentration of the first drift region; and
forming a drain region below the second drift region, a net impurity concentration of the drain region greater than the net impurity concentration of the second drift region.

26. The method of claim 25, further comprising:
forming an isolated polysilicon field plate below the polysilicon gate in each of the first trenches, wherein an interface between first and second drift regions is deeper than a top surface of the polysilicon field plate.

27. The method of claim 21, further comprising:
forming a third insulation layer that includes of BPSG on the second insulation layer before etching part of the second insulation layer.

28. The method of claim 21, wherein a thickness of the first insulation layer at the bottom of each of the first trenches is between two-thirds and one times a thickness of the first insulation layer at the sidewalls of the corresponding first trench.

29. The method of claim 21, wherein forming the first insulation layer on the bottom and the sidewalls of each of the first trenches and on the top surface of the semiconductor die comprises:
oxidizing the bottom and the sidewalls of each of the first trenches and the top surface of the semiconductor die using an oxidation temperature greater than 1000° C.
